(19) United States
(12) Patent Application Publication
(10) Pub. No.: US 2018/0069022 A1
(43) Pub. Date: Mar. 8, 2018

(54) THIN-FILM TRANSISTOR AND METHOD OF FABRICATING THE SAME

(71) Applicant: Shenzhen China Star Optoelectronics Technology Co., Ltd., Shenzhen, Guangdong (CN)

(72) Inventor: Jinming LI, Shenzhen, Guangdong (CN)

(73) Assignee: Shenzhen China Star Optoelectronics Technology Co., Ltd., Shenzhen, Guangdong (CN)

(21) Appl. No.: 15/113,822

(22) PCT Filed: May 12, 2016
(86) PCT No.: PCT/CN2016/081783

§ 371 Date: Jul. 23, 2016

(30) Foreign Application Priority Data
Jan. 28, 2016 (CN) 201610061597.X

(51) Int. Cl. H01L 27/12; H01L 29/66; H01L 29/786

(52) U.S. Cl. CPC H01L 27/12; H01L 29/78678; H01L 29/78669; H01L 29/66765

(57) ABSTRACT

The present disclosure provides a method of fabricating a TFT substrate. The method includes: forming a gate electrode on a substrate; forming a gate insulating layer on the substrate; forming a semiconductor layer on the gate insulating layer; processing the semiconductor layer for forming an ohmic contact layer; forming a metallic layer on the gate insulating layer; patterning the metallic layer and the ohmic contact layer for forming a source electrode and a drain electrode and for exposing the semiconductor layer located between the source electrode and the drain electrode; forming a passivation layer on the source electrode, the drain electrode, and the exposed semiconductor layer; forming a contact hole in the passivation layer; forming a pixel electrode connected to the drain electrode through the contact hole. The method is effective for forming a positive ohmic contact among the semiconductor layer, the source electrode, and the drain electrode.

### BACKGROUND OF THE INVENTION

### 1. Field of the Invention

The present invention relates to the field of wafer fabrication and flat display technology, and more particularly, to a thin-film transistor (TFT) substrate and a method of fabricating the TFT substrate.

### 2. Description of the Prior Art

In general, a semiconductor layer in a thin-film transistor (TFT) is formed by a metallic oxide thin film. The metallic oxide thin film is very sensitive to acid. Even weak acid can corrode the oxide semiconductor layer rapidly. It is quite easy to damage the oxide semiconductor layer when being etched to form a metallic source electrode and a metallic drain electrode.

Besides, the oxide semiconductor layer is always thinner, ranging from 30 nanometers (nm) to 50 nm. Even diluted hydrofluoric acid (HF) with a concentration of 500 to 1 the oxide semiconductor layer is etched within several seconds. In the conventional technology, an etching stop layer (ESL) is additionally arranged among the oxide semiconductor layer, the source electrode, and the drain electrode to protect the oxide semiconductor layer at the bottom from being affecting by an etching solution used to form the source electrode and the drain electrode. However, the additional ESL requires an additional photolithography process. The photolithography comprises filming, exposing, developing, etching, stripping, and so on. All in all, the production costs obviously increase while the yield rate of products decreases.

### SUMMARY OF THE INVENTION

An object of the present invention is to propose a TFT substrate without an additional ESL and a method of fabricating the TFT substrate to solve the deficiency of the conventional technology.

In one aspect of the present invention, a method of fabricating a thin-film transistor (TFT) substrate comprises: forming a gate electrode on a substrate; forming a gate insulating layer on the substrate for covering the gate electrode; forming a semiconductor layer on the gate insulating layer; processing the semiconductor layer with plasma for forming an ohmic contact layer comprising a predetermined thickness; forming a metallic layer on the gate insulating layer for covering the ohmic contact layer; patterning the metallic layer and the ohmic contact layer for forming a source electrode and a drain electrode and for exposing the semiconductor layer located between the source electrode and the drain electrode; forming a passivation layer on the source electrode, the drain electrode, and the exposed semiconductor layer; forming a contact hole for exposing the drain electrode in the passivation layer; forming a pixel electrode on the passivation layer, and the pixel electrode being connected to the drain electrode through the contact hole.

According to the exemplary embodiment of the present disclosure, the step of processing the semiconductor layer with plasma comprises: activating the semiconductor layer under temperatures between 250 and 500 Celsius (° C.); processing a surface of the semiconductor layer with plasma using argon (Ar)/nitrogen (N2) ions for forming an ohmic contact layer comprising a predetermined thickness.

According to the exemplary embodiment of the present disclosure, the step of patterning the metallic layer and the ohmic contact layer comprises: dry etching a part of the metallic layer, afterwards, etching the rest of the metallic layer and the ohmic contact layer using an etching solution containing hydrogen peroxide (H₂O₂) for forming the source electrode and the drain electrode and exposing the semiconductor layer located between the source electrode and the drain electrode.

According to the exemplary embodiment of the present disclosure, the metallic layer is made of molybdenum (Mo) or aluminum (Al).

According to the exemplary embodiment of the present disclosure, the gate electrode is made of Mo or Al.

According to the exemplary embodiment of the present disclosure, the gate insulating layer comprises a silicon oxide (SiOₓ) layer or a composite layer of SiOₓ and silicon nitride (SiNx).

According to the exemplary embodiment of the present disclosure, the passivation layer comprises the SiOₓ layer or the layers of SiOₓ and SiNx stacked from bottom to top.

According to the exemplary embodiment of the present disclosure, the pixel electrode comprises an indium tin oxide (ITO).

According to the exemplary embodiment of the present disclosure, the semiconductor layer comprises an indium gallium zinc oxide (IGZO).

In second aspect of the present invention, a thin-film transistor (TFT) substrate, comprises: a gate electrode, forming on a substrate; a gate insulating layer, formed on the substrate for covering the gate electrode; a semiconductor layer, formed on the gate insulating layer; a source electrode and a drain electrode, formed on both sides of the semiconductor layer; an ohmic contact layer, formed between the source electrode and the semiconductor layer and between the drain electrode and the semiconductor layer; a passivation layer, formed on the semiconductor layer, the source electrode, and the drain electrode; a pixel electrode, formed on the passivation layer and connected to the drain electrode.

According to the method of fabricating the TFT substrate proposed by the present invention, the addition of the ESL among the semiconductor layer, the source electrode, and the drain electrode is unnecessary. It is beneficial to reduction of production costs and simplification of the fabrication process. In addition, the method proposed by the present invention is effective for preventing a metallic oxide from being etched by a metallic etching solution and forming a positive ohmic contact among a semiconductor layer, a source electrode, and a drain electrode.

### BRIEF DESCRIPTION OF THE DRAWINGS

FIGS. 1-6 show a process of fabricating a TFT substrate according to an exemplary embodiment of the present invention.

### DETAILED DESCRIPTION OF PREFERRED EMBODIMENTS

The drawings illustrate embodiments of the invention and, together with the description, serve to explain the principles of the invention.

For better understanding embodiments of the present invention, the following detailed description taken in conjunction with the accompanying drawings is provided. Apparently, the accompanying drawings are merely for some of the embodiments of the present invention. Any ordinarily skilled person in the technical field of the present invention could still obtain other accompanying drawings without use laborious invention based on the present accompanying drawings.

In the following, the drawings illustrate embodiments of the invention and, together with the description, serve to explain the principles of the invention.

FIGS. 1-6 show a process of fabricating a TFT substrate according to an exemplary embodiment of the present invention.

As FIG. 1 shows, a gate electrode 110 is formed on a substrate 100. The substrate 100 is made from, but not limited to, transparent glass material which mainly comprises silicon dioxide (SiO₂).

Usually, the gate electrode 110 is formed on the substrate 100 with the method of physical vapor deposition (PVD). Specifically, a metallic dioxide is deposited on the substrate 100 with the PVD method. Subsequently, the gate electrode 110 with a predetermined pattern is formed with a lithography technique and an etching technique.

The gate electrode 110 is made of aluminum (Al) or molybdenum (Mo). However, it should not be taken as a limitation of the present invention. Instead, the gate electrode 110 may be made from other proper materials. The thickness of the gate electrode 110 ranges from 2000 Angstrom (Å) to 5500 Å in one of the exemplary embodiments in the present invention.

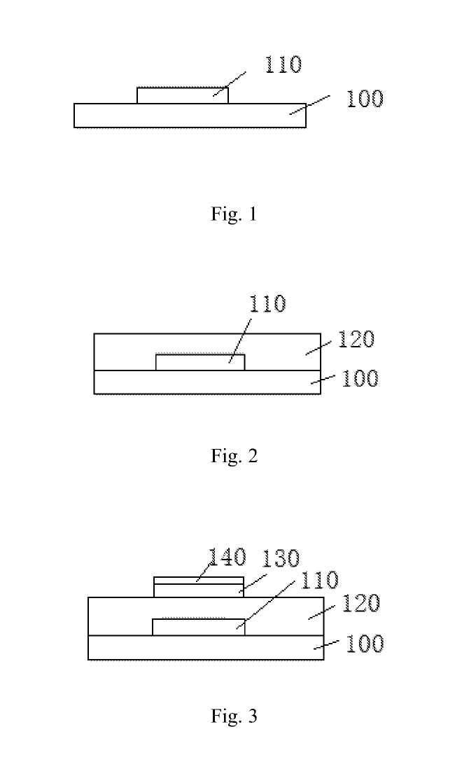

As FIG. 2 shows, a gate insulating layer 120 is formed on the substrate 100 to cover the gate electrode 110. Specifically, a metallic layer is deposited on the substrate 100 with the method of plasma enhanced chemical vapor deposition (PECVD). Afterwards, the gate insulating layer 120 is formed with the lithography technique and the etching technique. In the exemplary embodiment of the present invention, the gate insulating layer 120 forms either a single layer of silicon oxide (SiOₓ) or a composite layer of SiOₓ and silicon nitride (SiNx). In addition, the thickness of the gate insulating layer 120 ranges from fifteen hundred Å to four thousand Å in the exemplary embodiment of the present invention. However, it should not be taken as a limitation of the present invention.

As FIG. 3 shows, a semiconductor layer 130 and an ohmic contact layer 140 are formed on the gate insulating layer 120. Specifically, a metallic oxide is deposited on the gate insulating layer 120. Next, the semiconductor layer 130 with a predetermined pattern is formed with the lithography technique and the etching technique. Afterwards, the surface of the semiconductor layer 130 is activated under the temperatures between 250 and 500 Celsius (° C.) in the environment of air or oxidation. Subsequently, the surface of the semiconductor layer 130 undergoes a plasma process using argon (Ar)/nitrogen (N₂) ions with the method of dry etch or a chemical vapor deposition (CVD) machine. Finally, a part of the semiconductor layer 130 is transformed into the ohmic contact layer 140 having a predetermined thickness.

The semiconductor layer 130 comprises an indium gallium zinc oxide (IGZO) in this embodiment of the present invention. However, it should not be taken as a limitation of the present invention. Instead, the semiconductor layer 130 may be made from other proper metallic oxides. The thickness of the semiconductor layer 130 ranges from 400 Å to 1500 Å in one of the exemplary embodiments in the present invention. The thickness of the ohmic contact layer 140 ranges from ten Å to three hundred Å.

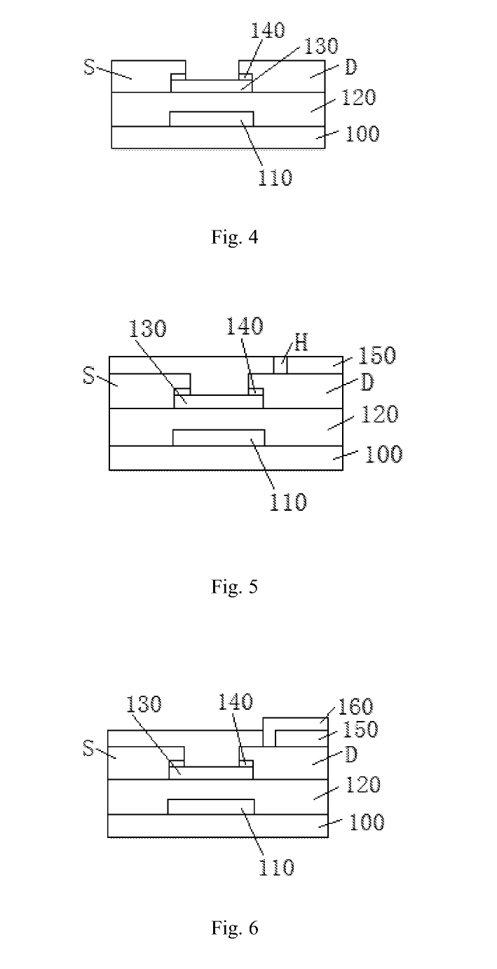

As FIG. 4 shows, a metallic layer is formed on the gate insulating layer 120 to cover the ohmic contact layer 140. Next, the metallic layer is patterned to form a source electrode S and a drain electrode D, and the semiconductor layer 130 located between the source electrode S and the drain electrode D is exposed. At first, the metallic layer is deposited on the gate insulating layer 120. Then, a part of the metallic layer is dry etched. Then, the rest of the metallic layer and the ohmic contact layer are etched using an etching solution containing hydrogen peroxide (H₂O₂) to form the source electrode S and the drain electrode D and to expose the semiconductor layer 130 located between the source electrode S and the drain electrode D.

The level of etching is controlled with a mode of end-point detection (EPD) to enhance the manufacturing accuracy in the present invention. The metallic layer comprises either Al or Mo or both of Al and Mo. Preferably, the metallic layer comprises Al and Mo. Also, Mo contacts the ohmic contact layer.

In this present invention, the surface of the semiconductor layer 130 undergoes a plasma process using the Ar/N₂ ions. Oxygen on the surface of the semiconductor layer 130 is bombarded by the Ar/N₂ with energy to increase the amount of indium (In) in the semiconductor layer 130, reduce resistors on the surface of the semiconductor layer 130, and to obtain a corresponding ohmic contact layer. Subsequently, the metallic layer formed on the ohmic contact layer is dry etched. Afterwards, the rest of the metallic layer and the ohmic contact layer are etched with an etching solution containing H₂O₂ to form the source electrode S, the drain electrode D, and an active layer with less faults.

As FIG. 5 shows, a passivation layer 150 is formed on the source electrode S, the drain electrode D, and the exposed semiconductor layer 130. A contact hole H is formed in the passivation layer 150. Specifically, the passivation layer 150 is formed on the source electrode S, the drain electrode D, and the exposed semiconductor layer 130 with the method of PECVD. Subsequently, the contact hole H is formed with the lithography technique and the etching technique. In the exemplary embodiment of the present invention, the passivation layer 150 comprises the SiOₓ layer or the composite layer of SiOₓ and SiNx. If the passivation layer 150 comprises the composite layer of SiOₓ and SiNx, the SiOₓ layer contacts the semiconductor layer 130. The thickness of the passivation layer 150 ranges from fifteen hundred Å to four thousand Å in the exemplary embodiment of the present invention. However, it should not be taken as a limitation of the present invention.

As FIG. 6 shows, a pixel electrode 160 is formed on the passivation layer 150. The pixel electrode 160 is connected to the drain electrode D through the contact hole H. An indium tin oxide (ITO) is deposited with the method of PVD. Subsequently, the pixel electrode 160 is formed with the lithography technique and the etching technique. The material of the pixel electrode 160 is not limited to the ITO; instead, other transparent conductors are usable. The thickness of the pixel electrode 160 ranges from three hundred Å to one thousand Å in the exemplary embodiment of the present invention. However, it should not be taken as a limitation of the present invention.

According to the method of fabricating the TFT substrate proposed by the present invention, an additional ESL among the semiconductor layer, the source electrode S, and the drain electrode D is unnecessary. It is beneficial to reduction of production costs and simplification of the fabrication process.

Moreover, the method proposed by the present invention is effective for preventing the metallic oxide from being etched by the metallic etching solution.

In addition, the method proposed by the present invention is effective for forming a positive ohmic contact among the semiconductor layer, the source electrode S, and the drain electrode D.

The method of fabricating the TFT is elaborated according the exemplary embodiments of the present invention. However, the claim scope of the present invention should not be taken as a limitation of the present invention.

What is claimed is:

1. A method of fabricating a thin-film transistor (TFT) substrate, comprising:
forming a gate electrode on a substrate;
forming a gate insulating layer on the substrate for covering the gate electrode;
forming a semiconductor layer on the gate insulating layer;
processing the semiconductor layer with plasma for forming an ohmic contact layer comprising a predetermined thickness;
forming a metallic layer on the gate insulating layer for covering the ohmic contact layer;
patterning the metallic layer and the ohmic contact layer for forming a source electrode and a drain electrode and for exposing the semiconductor layer located between the source electrode and the drain electrode;
forming a passivation layer on the source electrode, the drain electrode, and the exposed semiconductor layer;
forming a contact hole for exposing the drain electrode in the passivation layer;
forming a pixel electrode on the passivation layer, and the pixel electrode being connected to the drain electrode through the contact hole.

2. The method of claim 1, wherein the step of processing the semiconductor layer with plasma comprises:
activating the semiconductor layer under temperatures between 250 and 500 Celsius (° C.);
processing a surface of the semiconductor layer with plasma using argon (Ar)/nitrogen (N2) ions for forming an ohmic contact layer comprising a predetermined thickness.

3. The method of claim 1, wherein the step of patterning the metallic layer and the ohmic contact layer comprises: dry etching a part of the metallic layer, afterwards, etching the rest of the metallic layer and the ohmic contact layer using an etching solution containing hydrogen peroxide (H₂O₂) for forming the source electrode and the drain electrode and exposing the semiconductor layer located between the source electrode and the drain electrode.

4. The method of claim 1, wherein the metallic layer is made of molybdenum (Mo) or aluminum (Al).

5. The method of claim 1, wherein the gate electrode is made of Mo or Al.

6. The method of claim 1, wherein the gate insulating layer comprises a silicon oxide (SiOₓ) layer or a composite layer of SiOₓ and silicon nitride (SiNx).

7. The method of claim 1, wherein the passivation layer comprises the SiOₓ layer or the layers of SiOₓ and SiNx stacked from bottom to top.

8. The method of claim 1, wherein the pixel electrode comprises an indium tin oxide (ITO).

9. The method of claim 1, wherein the semiconductor layer comprises an indium gallium zinc oxide (IGZO).

10. A thin-film transistor (TFT) substrate, comprising:
a gate electrode, forming on a substrate;
a gate insulating layer, formed on the substrate for covering the gate electrode;
a semiconductor layer, formed on the gate insulating layer;
a source electrode and a drain electrode, formed on both sides of the semiconductor layer;
an ohmic contact layer, formed between the source electrode and the semiconductor layer and between the drain electrode and the semiconductor layer;
a passivation layer, formed on the semiconductor layer, the source electrode, and the drain electrode;
a pixel electrode, formed on the passivation layer and connected to the drain electrode.
